(19) United States
(12) Patent Application Publication
(10) Pub. No.: US 2021/0062333 A1
(43) Pub. Date: Mar. 4, 2021

(54) MOISSANITE ORNAMENT AND METHOD FOR COATING DIAMOND FILM ON SURFACE OF MOISSANITE ORNAMENT

(71) Applicant: AAA GEMS CO., LIMITED, SHENZHEN (CN)

(72) Inventors: Jinxin HE, SHENZHEN (CN); Fanxiu LV, SHENZHEN (CN); Lifu HEI, SHENZHEN (CN)

(73) Assignee: AAA GEMS CO., LIMITED

(21) Appl. No.: 16/559,636

(22) Filed: Sep. 4, 2019

(51) Int. Cl. C23C 16/27; C23C 16/02; C23C 16/50; C23C 16/458

(52) U.S. Cl. CPC C23C 16/276; C23C 16/0254; C23C 16/4583; C23C 16/50; C23C 16/0227

(57) ABSTRACT

A moissanite ornament, wherein the surface of the moissanite is coated with a diamond film. A method for coating a diamond film on a surface of a moissanite, including: Step 1: performing ultrasonic grinding pretreatment on the moissanite ornament in the nano-diamond powder suspension; Step 2: taking the moissanite ornament out from the nano-diamond powder suspension, and washing clean; Step 3: pressing the moissanite ornament into a preset shape-preserving sample platform to maintain; Step 4: placing, the moissanite ornament together with the shape-preserving sample platform into a diamond film deposition furnace to perform a plasma treatment; Step 5: introducing methane to conduct in-situ diamond film deposition. The moissanite coated with the diamond film on the surface provided by the present disclosure can greatly improve the surface hardness while maintaining the optical properties of the moissanite, thereby improving the scratch resistance performance of the moissanite.

### TECHNICAL FILED

The present disclosure relates to the field of jewelry, in particular to a moissanite ornament, and to a method for coating a diamond film on the surface of a moissanite ornament.

### BACKGROUND

The internal structure, value and appearance of moissanite are strikingly similar to diamonds. It is difficult to distinguish using diamond pen detection, but moissanite can shining brighter than diamonds, fire color is more amazing, and the price is cheaper than diamond, so moissanite is often used to process into a jewelry.

However, the hardness of moissanite is lower than that of diamond, so the scratch resistance is much worse than that of diamond.

### SUMMARY

For the technical problem of poor scratch resistance of moissanite, the present disclosure is to provide a moissanite with high surface hardness. In addition, the present disclosure also provides a method for coating a diamond film on the surface of the moissanite.

A moissanite ornament, including a surface of the moissanite ornament is coated with a diamond film, and Mohs hardness scale of the moissanite is 9.9 to 10.00.

Further, the diamond film has an average grain size from 100 nm to 200 nm.

A method for coating a diamond film on a surface of a moissanite ornament, including: Step 1: performing ultrasonic grinding pretreatment on the moissanite in the nano-diamond powder suspension; Step 2: taking the moissanite out from the nano-diamond powder suspension, and washing clean; Step 3: pressing the moissanite into a preset shape-preserving sample platform to maintain; Step 4: placing the moissanite together with the shape-preserving sample platform into a diamond film deposition furnace to perform a plasma treatment; Step 5: introducing methane to conduct in-situ diamond film deposition.

Preferably, nano-diamond powders in the nano-diamond powder suspension in the step 1 has a particle size of 5 nm to 200 nm, a concentration of the nano-diamond powder in the nano-diamond powder suspension is from 5% to 20%.

Preferably, the ultrasonic grinding pretreatment time is from 2 h to 6 h.

Preferably, a material of the shape-preserving sample platform in step 3 is pure copper or graphite.

Preferably, the shape-preserving sample platform is provided with a recess for maintaining a moissanite ornament, and a pressure to press the moissanite ornament into the recess is 50 Kgf to 250 Kgf in step 3.

Preferably, the plasma treatment in step 4 employs direct current arc plasma jet or microwave plasma jet.

Preferably, a temperature of the plasma treatment is from 700° C. to 1000° C. and the plasma treatment time is 5 min to 30 min.

Preferably, a concentration of the methane in step 5 is from 0.5% to 10%, a pressure of the diamond film deposition furnace is 3 kPa to 20 kPa, and a deposition time is 5 min to 120 min.

The moissanite ornament coated with the diamond film on the surface thereof provided by the present disclosure can greatly improve the surface hardness while maintaining the optical properties of the moissanite, thereby improving the scratch resistance performance of the moissanite. In addition, by the method of the present disclosure, it can obtain a uniform and dense diamond film coating on the surface of the moissanite with an excellent optical properties, which improves the surface hardness of the moissanite ornament.

### BRIEF DESCRIPTION OF THE DRAWINGS

FIG. 1 is a surface AFM (atomic force microscope) topography of a moissanite coated with a diamond film.

FIG. 2 is a typical Raman spectrum of the moissanite coated with a diamond film.

FIG. 3 is a view showing the scratch of the moissanite without the diamond film being magnified 100 times under the microscope after the experiment of the anti-diamond needle scratching ability.

FIG. 4 is a view of the scratch of the moissanite coated with the diamond film magnified 200 times under the microscope after the experiment of the anti-diamond needle scratching ability.

FIG. 5 is a schematic view showing the structure of a shape-preserving sample platform used in the present disclosure.

### DETAILED DESCRIPTION OF THE EMBODIMENTS

The present disclosure will be described in detail below with reference to FIGS. 1 to 5.

A moissanite ornament with a diamond film on the surface thereof, taking the moissanite diamond as an example, referring to FIG. 1, it shows the topography of the surface of the moissanite diamond sample with the diamond film coating observed under AFM (atomic force microscopy). Wherein the coating is dense and uniform, and the average grain size is about from 100 nm to 200 nm, Mohs hardness is 9.9-10.00.

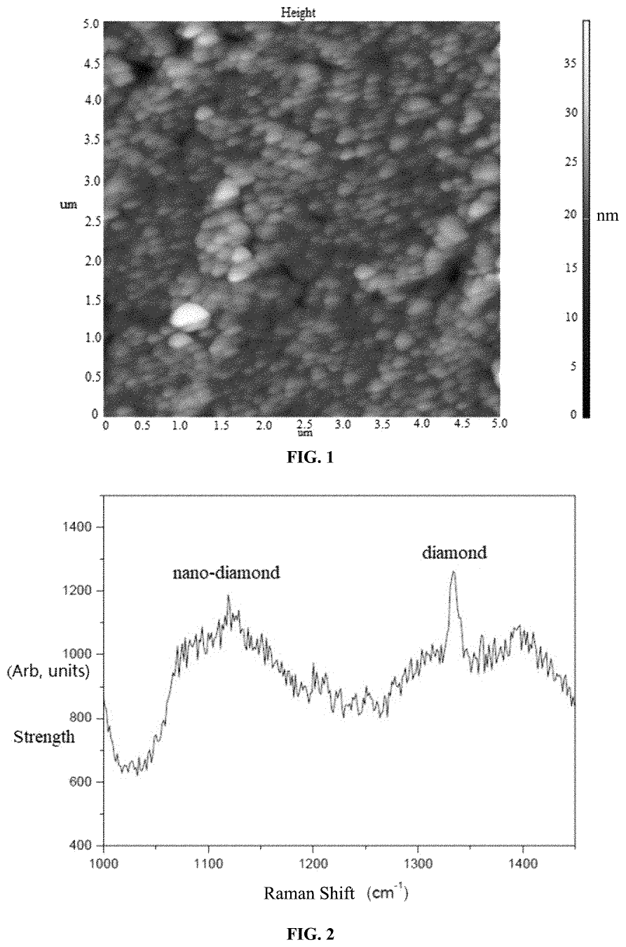

Referring to FIG. 2, the Raman characteristic peak of the diamond at 1331 cm⁻¹ can be seen. The scattering peak located near 1120 cm⁻¹ is related to the grain size of the diamond film and it is a representation of very fine grains. The appearance of this peak is consistent with the fine grains shown in FIG. 1.

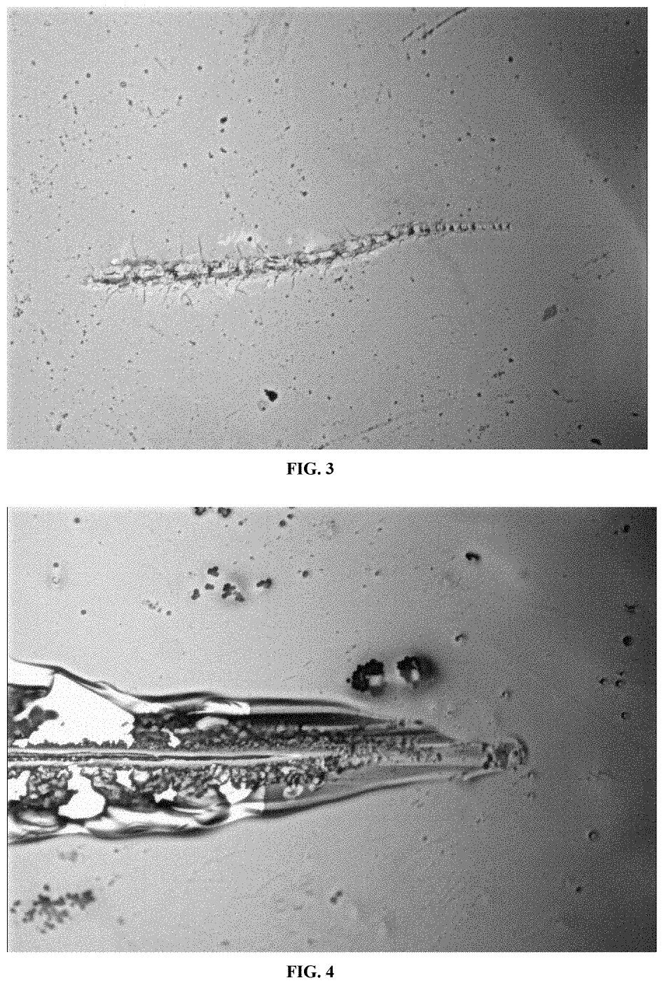

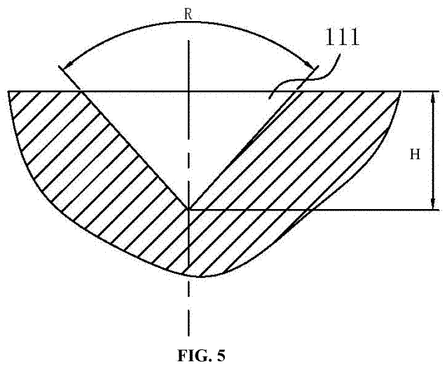

Referring to FIGS. 3 and 4, when the moissanite coated with the diamond film and the moissanite without the diamond film are conducted the experiment of the anti-diamond needle scratching ability under the positive pressure of 20 N at maximum, the positive pressure is gradually increased from zero (actually the preload force is 0.02 N) to 20 N in the scratching process, and the scratching distance traveled during this period (1 minute) is 2 mm.

Wherein, scratching marks can be visible from the optical microscope (magnification 100) when the positive pressure performed on the moissanite without diamond film is above 8N, and a series of sharp cracks appear. However, under the same conditions, there is no visible scratching marks shown on the moissanite coated with the diamond film on the surface thereof. For the moissanite with the diamond film on the surface thereof, it can be seen from the optical microscope (magnification of 200) that the diamond film is fractured when the positive pressure is very close to the maximum pressure (20N), and there is a sign of brittle fracture, the crack is flat like a knife cut, and the film is opened and rolled up. Therefore, it can be turned out by experiments that the moissanite with a diamond film on surface thereof is substantially fractured only when the pressure is sufficiently large (close to 20N). Compared with moissanite without a diamond film, the scratch resistance of the moissanite with a diamond film is greatly improved.

A method for coating a diamond film on the surface of a moissanite will be described as below.

The method includes the following steps: Step 1: ultrasonic grinding pretreatment is conducted on the moissanite in the nano-diamond powder suspension. Wherein the nano-diamond powder in the nano-diamond powder suspension has a particle size of 5 nm to 200 nm, the nano-diamond powder suspension has a concentration of 5%® to 20%, and the ultrasonic grinding pretreatment time is 2 h to 6 h. The purpose of this step is mainly to increase the nucleation density of the diamond film deposition so that the nucleation density of the diamond film is greater than 10¹⁰ cm⁻².

After ultrasonic grinding pretreatment, in step 2: the moissanite is taken out from the nano-diamond powder suspension and washed clean, wherein the washing is sequentially used ultrasonically washing with deionized water and absolute ethanol, and then dried by cold air.

After ultrasonic grinding pre-treatment and washing clean of the moissanite ornament, in step 3: the moissanite is pressed into a preset shape-preserving sample platform to maintain. Wherein, taking the moissanite diamond as an example, in order to maintain the moissanite diamond, referring to FIG. 5, a recess 111 for maintaining a moissanite ornament can be disposed in the shape-preserving sample platform. The recess 111 is an inverted cone shape and a depth H of the recess 111 is about ⅘ of the depth of the moissanite diamond, and the cone angle R of the inverted cone is approximately 96°, which can allow an error of 0° to 2°. In order to facilitate the press-in of the moissanite, the material of the shape-preserving sample platform is adopted the material such as pure copper or graphite, which is slightly soft and has good thermal conductivity. The moissanite diamond can be pressed into the recess of the shape-preserving sample platform by applying a pressure of 50 Kgf to 250 Kgf.

After ultrasonic grinding pretreatment and pressing the moissanite diamond into the recess of the shape-preserving sample platform, in step 4, the moissanite diamond is placed together with the shape-preserving sample platform into a diamond film deposition furnace for performing plasma treatment. In step 4, the diamond film deposition methods such as direct current arc plasma jet (DC Arc Plasma Jet) CVD, microwave plasma jet CVD (MWCVD), and hot wire CVD (HFCVD) and etc. can be used for diamond coating of moissanite diamond. However, the hot wire CVD is too low in the degree of gas activation, resulting in a too low atomic hydrogen concentration, so that the hot wire CVD is difficult to obtain a diamond film coating having good optical properties. Therefore, in step 4, the plasma treatment uses a direct current arc plasma jet or a microwave plasma jet. The plasma treatment temperature is 700° C. to 1000° C., and the plasma treatment time is 5 min to 30 min, so as to completely remove the influence of any organic roots (derived from nano-diamond powder suspension) on the surface of moissanite diamond on the deposition of diamond film, and to activate the surface state of moissanite diamond samples, which facilitates the uniform deposition of the diamond film and improves diamond adhesion of the diamond film.

After the plasma treatment is completed, in step 5: the methane is introduced, and then the in-situ diamond film deposition is performed. In this step, the concentration of the methane is 0.5% to 10%, the surface temperature of the moissanite diamond is 700° C. to 1000° C., the pressure of the deposition furnace is set to 3 kPa-20 kPa, and the deposition time is 5 min to 120 min.

After the deposition is completed, the sample of the moissanite diamond coated with film can be taken out after cooling for 10 minutes.

Further, a diamond film coating of a moissanite diamond (1 carat) having a diameter of 6.5 mm is given as an example as shown below.

First, a moissanite diamond sample is ultrasonically ground in a 30 nm diamond powder suspension for 3 hours.

The moissanite diamond sample is taken out and washed clean.

The moissanite diamond sample is pressed with a force of 150 kg into the prefabricated inverted conical recess of the copper shape-preserving sample platform having a height of 30 mm and a diameter of 50 mm.

The moissanite diamond sample is placed in a direct current arc plasma CVD diamond film deposition furnace and treated in an argon/hydrogen plasma for 5 minutes (Ar: 3 slm; H2: 8 slm; chamber pressure: 3 to 6 kPa; plasma torch current: 190 A; voltage: 97V). Then, the methane is introduced into the plasma at a flow rate of 50 sccm to 240 seem, and the surface temperature of the sample is 700° C. to 1000° C. for 5 min to 30 min. After that, the current is cut off and the diamond film deposition is stopped, and then, the moissanite diamond sample coated with film is taken out after cooling for 10 minutes.

The appearance of the moissanite diamond sample coated with diamond film obtained by this method compares with the appearance of the uncoated moissanite diamond, it can be seen that the diamond film coating has no influence on the optical properties (fire color) of the moissanite diamond. In addition, the surface of the moissanite sample coated with diamond film is observed under AFM (atomic force microscope) that the coating structure is dense and uniform, and the average grain size is about 100 nm to 200 nm.

The description above is only the embodiment of the present disclosure, and is not intended to limit the scope of the present disclosure. Any equivalent structure or equivalent process transformation directly or indirectly applied to other related technical fields, which is made by using the contents of the specification of the present disclosure, should be within the scope of the present disclosure.

1. A moissanite ornament, comprising a surface of the moissanite ornament is coated with a diamond film, and Mohs hardness scale of the moissanite jewelry is 9.9 to 10.00.

2. The moissanite ornament according to claim 1, wherein the diamond film has an average grain size from 100 nm to 200 nm.

3. A method for coating a diamond film on a surface of a moissanite ornament, comprising
Step 1: performing ultrasonic grinding pretreatment on the moissanite ornament in the in a nano-diamond powder suspension;
Step 2: taking the moissanite ornament out from the nano-diamond powder suspension, and washing clean;
Step 3: pressing the moissanite ornament into a preset shape-preserving sample platform to maintain;
Step 4: placing the moissanite ornament together with the shape-preserving sample platform into a diamond film deposition furnace to perform a plasma treatment;
Step 5: introducing methane to conduct in-situ diamond film deposition;
wherein the ultrasonic grinding pretreatment time is from 2 h to 6 h; a material of the shape-preserving sample platform in step 3 is pure copper; and
the plasma treatment in step 4 employs direct current arc plasma jet or microwave plasma jet to remove an influence of organic roots on deposition of diamond film, in which the organic roots is derived from the nano-diamond powder suspension on the surface of moissanite ornament.

4. The method for plating a diamond film on a surface of a moissanite ornament according to claim 3, wherein nano-diamond powders in the nano-diamond powder suspension in the step 1 has a particle size of 5 nm to 200 nm, a concentration of the nano-diamond powder in the nano-diamond powder suspension is from 5% to 20%.

5. (canceled)

6. (canceled)

7. The method for coating a diamond film on a surface of a moissanite ornament according to claim 3, wherein the shape-preserving sample platform is provided with a recess for maintaining a moissanite ornament, and a pressure to press the moissanite ornament into the recess is 50 Kgf to 250 Kgf in step 3.

8. (canceled)

9. The method for coating a diamond film on a surface of a moissanite ornament according to claim 3, wherein a temperature of the plasma treatment is from 700° C. to 1000° C. and the plasma treatment time is 5 min to 30 min.

10. The method for coating a diamond film on a surface of a moissanite ornament according to claim 3, wherein a concentration of the methane in step 5 is from 0.5% to 10%, a pressure of the diamond film deposition furnace is 3 kPa to 20 kPa, and a deposition time is 5 min to 120 min.
